(19) United States
(12) Patent Application Publication
(10) Pub. No.: US 2025/0185425 A1
(43) Pub. Date: Jun. 5, 2025

(54) Display Device and Method for Fabricating the Same

(71) Applicant: LG Display Co., Ltd., Seoul (KR)

(72) Inventor: Tae Kyoung Kim, Paju-si (KR)

(21) Appl. No.: 18/775,989

(22) Filed: Jul. 17, 2024

(30) Foreign Application Priority Data
Nov. 30, 2023 (KR) 10-2023-0171097

(51) Int. Cl. H01L 33/48; H01L 25/16; H01L 33/60

(52) U.S. Cl. CPC H10H 20/8506; H01L 25/167; H10H 20/856

(57) ABSTRACT

A display device includes a substrate, a plurality of bank patterns disposed on the substrate, at least one concave portion formed in one of the plurality of bank patterns, a first electrode disposed in the concave portion, a reflection layer disposed on the first electrode, a light-emitting element disposed on the first electrode; and a first optical layer surrounding a side surface of the light-emitting element.

### CROSS-REFERENCE TO RELATED APPLICATION

This application claims priority to and the benefit of Republic of Korea Patent Application No. 10-2023-0171097, filed Nov. 30, 2023, which is incorporated herein by reference in its entirety.

### BACKGROUND

### 1. Technical Field

An embodiment relates to a display device using an inorganic light-emitting diode as a light source and a method for fabricating the same.

### 2. Discussion of Related Art

Electroluminescent display devices include an organic light-emitting display device in which an organic light-emitting diode (OLED) is disposed, and an inorganic light-emitting display device (hereinafter referred to as an “LED display device”) in which an inorganic light-emitting diode (hereinafter referred to as an “LED”) is disposed.

Since the electroluminescent display device displays an image using a self-luminous element, it does not require a separate light source, e.g., a backlight unit, so it may be implemented in thin and various forms.

The organic light-emitting display device requires a design that prevents or at least reduces the permeation of oxygen and moisture since the permeation of moisture and oxygen can cause oxidation between an organic light-emitting layer and an electrode.

Recently, as an example of the inorganic light-emitting display device, a micro LED display device in which a micro LED is disposed in pixels has been gaining attention as a next generation display device. The micro LED may be an inorganic LED having a size of 100 μm or less. The micro LED may be fabricated by a separate semiconductor process, and may be transferred to a pixel position on a display panel substrate of a display device and disposed in each sub-pixel by color.

### SUMMARY

The present specification provides a display device and a method for fabricating the same, capable of preventing or at least reducing the loss of a light-emitting element during a process of removing and re-applying a first optical layer due to a defect in the first optical layer, by transferring the light-emitting element into a concave portion formed in a plurality of bank patterns.

The problem to be solved by the present specification is not limited to the problem mentioned above, and other problems not mentioned herein will be clearly understood by those skilled in the art from the following description.

The above problem is solved by a display device including: a substrate; a plurality of bank patterns disposed on the substrate; at least one concave portion formed in each of the plurality of bank patterns; a first electrode disposed in the concave portion; a reflection region disposed on the first electrode; a light-emitting element disposed on the first electrode in the concave portion; and a first optical layer disposed to surround the side surface of the light-emitting element.

According to the present specification, the light-emitting element may be transferred to the bottom surface of the concave portion in the bank pattern, so that the concave portion may act as a breakwater or dam to prevent or at least reduce the loss of the light-emitting element caused by water pressure or wind pressure during the process of removing foreign matter or a chemical solution used to remove a defective first-first optical layer. As a result, even if a defect occurs in the first-first optical layer, the first-first optical layer may be removed and reapplied to continue product production, thereby reducing costs.

Embodiments described herein also include a display device comprising a substrate, a pixel driving circuit on the substrate, one or more insulating layers on the pixel driving circuit, and a bank including a plurality of protrusion portions on the one or more insulation layers. At least one of the plurality of protrusion portions includes a concave portion. The display device further includes a pixel. The pixel includes a plurality of sub-pixels. At least one of the plurality of sub-pixels includes a first electrode in the concave portion, a light-emitting element disposed on the first electrode at least in part in the concave portion, and a second electrode on the light-emitting element. An area of a bottom surface of the concave portion is greater than an area of a bottom surface of the light-emitting element.

In some embodiments, the at least one of the plurality of sub-pixels further includes a reflection layer surrounding where the first electrode and the light-emitting element are in contact with each other. In some embodiments, the at least one of the plurality of sub-pixels further includes a reflection layer on the bottom surface and a side surface of the concave portion. In some embodiments, the display device further includes an optical layer between the reflection layer and the light-emitting element within the concave portion.

The various beneficial advantages and effects of the present specification are not limited to the above description, and other effects not mentioned will be clearly understood by those skilled in the art from the following description.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a diagram illustrating a display device according to one embodiment of the present disclosure.

FIG. 2 is an enlarged view of area A of FIG. 1 according to one embodiment of the present disclosure.

FIG. 3 is a diagram illustrating a partial area of a pixel according to one embodiment of the present disclosure.

FIG. 4 is a cross-sectional view taken along line I-I′ in FIG. 3 according to one embodiment of the present disclosure.

FIG. 5 is a cross-sectional view taken along line II-II′ in FIG. 3 according to one embodiment of the present disclosure.

FIG. 6 is a cross-sectional view taken along line III-III′ in FIG. 3 according to one embodiment of the present disclosure.

FIG. 7 is a cross-sectional view illustrating an example in which a main light-emitting element and a sub-light-emitting element are electrically connected to a pixel driving circuit according to one embodiment of the present disclosure.

FIG. 8 is a diagram illustrating a display device according to one embodiment of the present disclosure.

FIG. 9 is a cross-sectional view taken along line IV-IV′ in FIG. 8 according to one embodiment of the present disclosure.

FIG. 10 is a diagram illustrating a partial area of a pixel according to one embodiment of the present disclosure.

FIG. 11 is a cross-sectional view taken along line Y-Y′ in FIG. 8 according to one embodiment of the present disclosure.

FIGS. 12A and 12B are perspective views illustrating a fabricating process of a display device according to one embodiment of the present disclosure.

FIGS. 13A to 13E are cross-sectional views of a fabricating process of a display device in a direction Z-Z′ of FIG. 8 according to one embodiment of the present disclosure.

### DETAILED DESCRIPTION

The advantages and features of the present disclosure, and methods of achieving them will be apparent from the embodiments described in detail below in conjunction with the accompanying drawings. However, the present disclosure is not limited to the following embodiments, which may be implemented in various different forms. Rather, the present embodiments will allow those skilled in the art to fully understand the scope of the present disclosure.

The shapes, sizes, proportions, angles, numbers and the like shown in the accompanying drawings for the purpose of describing the embodiments of the present disclosure are merely examples, and the present disclosure is not limited thereto. Like reference numerals generally denote like elements throughout the present specification. Further, in describing the present disclosure, detailed descriptions of known related technologies may be omitted so as not to unnecessarily obscure the subject matter of the present disclosure.

The terms such as “comprising,” “including,” and “having” used herein are generally intended to allow other components to be added unless the terms are used with the term “only.” References to the singular shall be construed to include the plural unless expressly stated otherwise.

When interpreting components, they are interpreted to include a margin of error even if it is not explicitly stated.

When describing a positional or interconnected relationship between two components, such as “on top of,” “above,” “below,” “next to,” “connect or couple with,” “crossing,” “intersecting,” etc., one or more other components may be interposed between them unless “immediately” or “directly” is used.

When a temporal contextual relationship is described, such as “after,” “following,” “next to,” or “before,” it may not be continuous on a time scale unless “immediately” or “directly” is used.

First, second, and the like may be used before the names of the components to distinguish the components, but the function or structure thereof is not limited by such ordinal number or component name. For ease of description, the ordinal numbers placed before the names of the same components may differ between embodiments.

The following embodiments may be combined or associated with each other in whole or in part, and various types of interlocking and driving are technically possible. The embodiments may be implemented independently of each other or together in an interrelated relationship.

Hereinafter, various embodiments of the present disclosure will be described in detail with reference to the accompanying drawings.

A display device according to one embodiment of the present specification includes a display panel having a display area or screen on which an image is displayed, and a pixel driving circuit that drives pixels of the display panel. The display area includes a pixel area in which the pixels are disposed. The pixel area includes a plurality of emission regions. A light-emitting element is disposed in each of the emission regions. The pixel driving circuit may be embedded in the display panel.

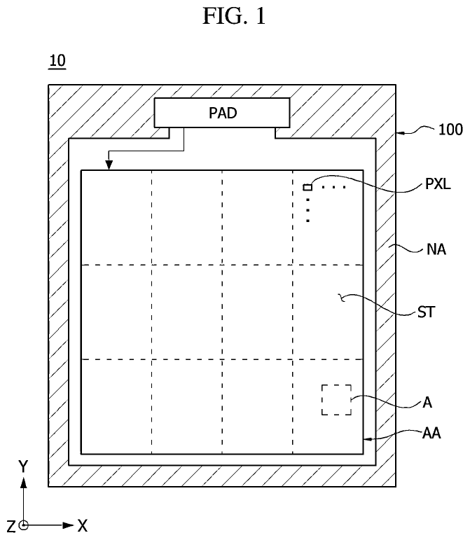

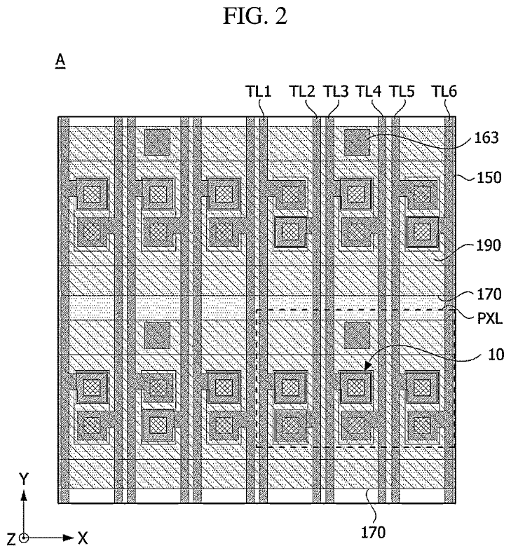

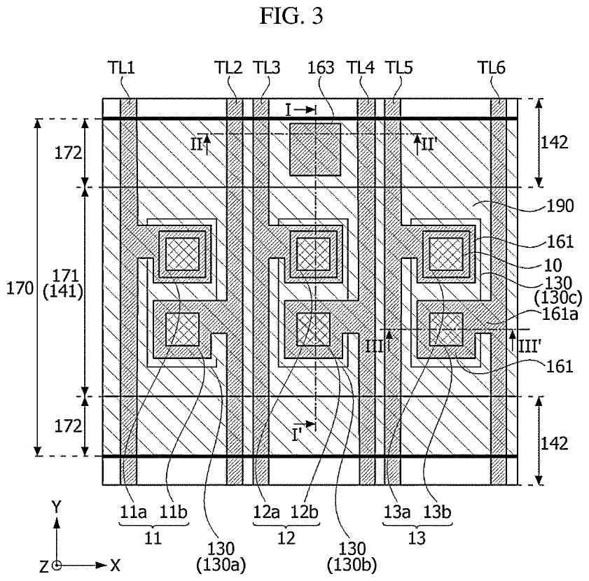

FIG. 1 is a diagram illustrating a display device according to one embodiment of the present specification. FIG. 2 is an enlarged view of area A of FIG. 1 according to one embodiment of the present specification. FIG. 3 is a diagram illustrating a partial area of a pixel according to one embodiment of the present specification.

Referring to FIGS. 1 and 2, a display device 100 according to an embodiment of the present specification includes the display panel on which an input image is visually reproduced. The display panel may include a display area AA in which an image is displayed and a non-display area NA in which an image is not displayed. In the non-display area NA, various wires and driving circuits may be mounted, and a pad portion PAD to which an integrated circuit, a printed circuit, and the like are connected may be disposed. Here, the display panel may have a rectangular structure having a width in an X-axis direction, a length in a Y-axis direction, and a thickness in a Z-axis direction. In this case, the width and length of the display panel may be set as various design values depending on the application field of the display device. The X-axis direction may refer to a width direction, a row direction, or a horizontal direction, the Y-axis direction may refer to a length direction, a column direction, or a vertical direction, and the Z-axis direction may refer to an up-down direction or a thickness direction. In addition, the X-axis direction, the Y-axis direction, and the Z-axis direction may be perpendicular to each other, but they may also refer to different directions that are not perpendicular to each other. Accordingly, each of the X-axis direction, the Y-axis direction, and the Z-axis direction may be described as one of a first direction, a second direction, and a third direction. A plane extending in the X-axis and Y-axis directions may refer to a horizontal plane.

A plurality of light-emitting elements 10 disposed in the display area AA to form a pixel PXL may be micro-sized inorganic light-emitting elements or micro light-emitting diodes (micro LEDs). The inorganic light-emitting element may be grown on a silicon wafer and then attached to the display panel through a transfer process.

The transfer process of the light-emitting element 10 may be performed for each pre-divided region. In FIG. 1, the display area AA is shown as being divided into twelve transfer regions ST, but the size or the number of divisions of the transfer regions is not limited thereto. The transfer process may be sequentially or simultaneously performed for first to 12th transfer regions ST. The plurality of light-emitting element 10 may include a blue light-emitting element 10, a green light-emitting element 10, and a red light-emitting element 10, which may be sequentially transferred to the transfer region ST.

In the non-display area NA, a data driving circuit or a gate driving circuit may be disposed, and wires for supplying a control signal for controlling the driving circuits may be disposed. Here, the control signal may include various timing signals including a clock signal, an input data enable signal, and synchronization signals, and may be received through the pad portion PAD.

The pixels PXL may be driven by the pixel driving circuit. The pixel driving circuit may receive a driving voltage, an image signal (digital signal), a synchronization signal synchronized with the image signal, and the like and output an anode voltage and a cathode voltage of the light-emitting element 10 to drive the plurality of pixels. The driving voltage may be a high potential voltage EVDD. The cathode voltage may be a low potential voltage EVSS applied in common to the pixels. The anode voltage may be a voltage corresponding to a pixel data value of the image signal. The pixel driving circuit may be disposed in the non-display area NA, or may be disposed below the display area AA.

Each of the pixels PXL may include a plurality of sub-pixels having different colors. For example, the plurality of sub-pixels may include a red sub-pixel in which the light-emitting element 10 that emits light of a red wavelength is disposed, a green sub-pixel in which the light-emitting element 10 that emits light of a green wavelength is disposed, and a blue sub-pixel in which the light-emitting element 10 that emits light of a blue wavelength is disposed. The plurality of sub-pixels may further include a white sub-pixel.

Referring to FIGS. 2 and 3, the plurality of pixels PXL may be successively arranged in the first direction (the X-axis direction) and the second direction (the Y-axis direction). The plurality of sub-pixels of the same color may be disposed within the pixel of the display area AA. For example, each of the plurality of pixels may include a first red sub-pixel in which a first-first light-emitting element 11a that emits light of a red wavelength is disposed, a second red sub-pixel in which a first-second light-emitting element 11b that emits light of a red wavelength is disposed, a first green sub-pixel in which a second-first light-emitting element 12a that emits light of a green wavelength is disposed, a second green sub-pixel in which a second-second light-emitting element 12b that emits light of a green wavelength is disposed, a first blue sub-pixel in which a third-first light-emitting element 13a that emits light of a blue wavelength is disposed, and a second blue sub-pixel in which a third-second light-emitting element 13b that emits light of a blue wavelength is disposed. The first-first light-emitting element 11a, the second-first light-emitting element 12a, and the third-first light-emitting element 13a may be regarded as main light-emitting elements. The first-second light-emitting element 11b, the second-second light-emitting element 12b, and the third-second light-emitting element 13b may be regarded as sub-light-emitting elements.

One sub-pixel may include at least one or more light-emitting elements, and in the event that one light-emitting element becomes defective, the luminance of another light-emitting element may be increased to adjust the luminance of the sub-pixel. However, the present disclosure is not necessarily limited thereto, and one sub-pixel may include only one light-emitting element.

A plurality of first electrodes 161 may each be disposed below the light-emitting element 10, and may be selectively connected to a plurality of signal wires TL (TL1 to TL6) by an extension portion 161a. The high potential voltage may be applied to the pixel driving circuit through the signal wires TL1 to TL6. The signal wires TL1 to TL6 and the first electrode 161 may be formed as an integrated electrode pattern during an electrode patterning process.

For example, a first signal wire TL1 may be connected to the anode electrode of the first red sub-pixel, and a second signal wire TL2 may be connected to the anode electrode of the second red sub-pixel. A third signal wire TL3 may be connected to the anode electrode of the first green sub-pixel, and a fourth signal wire TL4 may be connected to the anode electrode of the second green sub-pixel. A fifth signal wire TL5 may be connected to the anode electrode of the first blue sub-pixel, and a sixth signal wire TL6 may be connected to the anode electrode of the second blue sub-pixel. When one sub-pixel includes only one light-emitting element, the number of the signal wires TL may be reduced by half.

A second electrode 170 may be a cathode electrode that is disposed in each row and applies a cathode voltage to the light-emitting elements 10 arranged successively in the first direction (the X-axis direction). The plurality of second electrodes 170 may be spaced apart from each other in the second direction (the Y-axis direction). The plurality of second electrodes 170 may be connected to the cathode voltage through a contact electrode 163. Each of the plurality of second electrodes 170 may be electrically connected to the contact electrode 163. However, the present disclosure is not necessarily limited thereto, and the second electrode 170 may be configured as one electrode layer without being divided into a plurality of electrodes and may function as a common electrode.

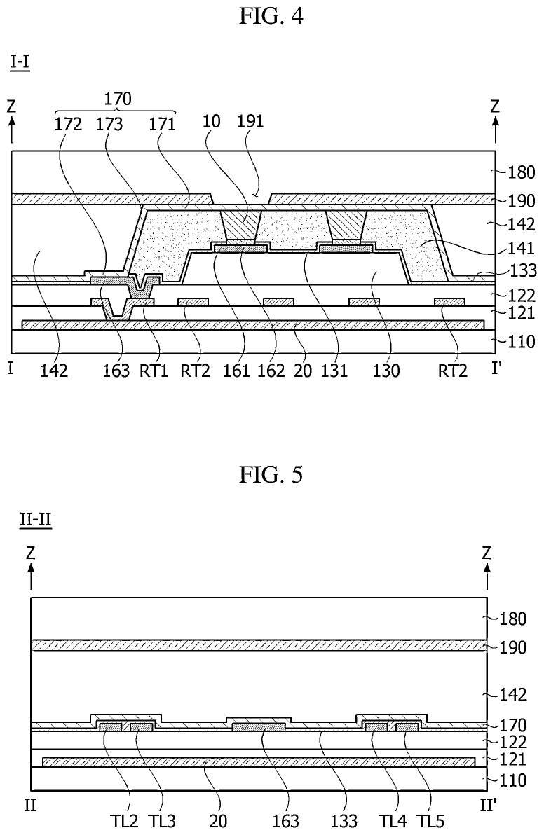

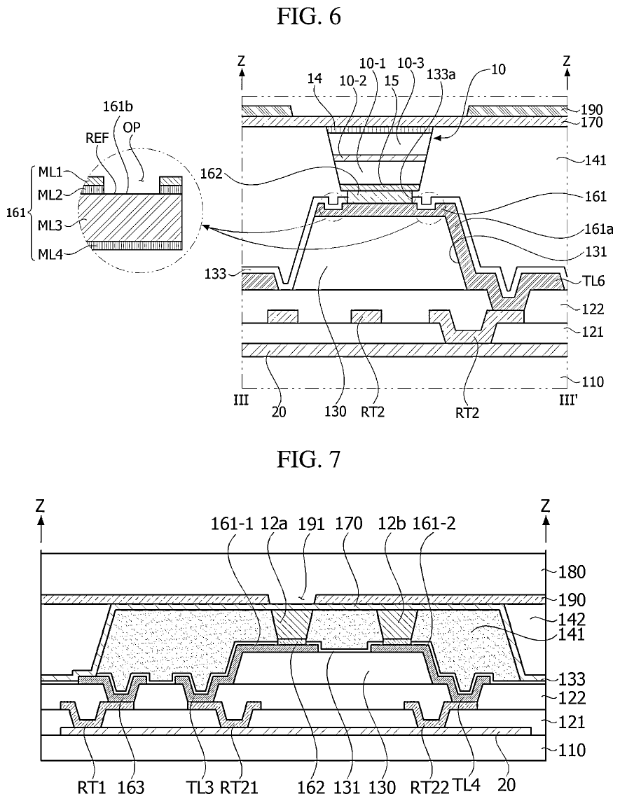

FIG. 4 is a cross-sectional view taken along line I-I′ in FIG. 3 according to one embodiment of the present specification. FIG. 5 is a cross-sectional view taken along line II-II′ in FIG. 3 according to one embodiment of the present specification. FIG. 6 is a cross-sectional view taken along line III-III′ in FIG. 3 according to one embodiment of the present disclosure. FIG. 7 is a cross-sectional view illustrating an example in which two light-emitting elements are connected to a pixel driving circuit according to one embodiment of the present specification.

Referring to FIGS. 3 to 5, the display device according to an embodiment includes the plurality of first electrodes 161 and the contact electrode 163 disposed above a substrate 110, the plurality of light-emitting elements 10 disposed on the plurality of first electrodes 161, a first optical layer 141 disposed between the plurality of light-emitting elements 10, and the second electrode 170 disposed on the plurality of light-emitting elements 10. In some embodiments, the first electrode is on a top surface 130-2 and a side surface 130-1 of a protrusion portion of the bank 130 (see FIG. 11). In some embodiments, the contact electrode 163 is on one of the one or more insulating layers 122. The substrate 110 may be made of plastic having flexibility. For example, the substrate 110 may be fabricated as a single-layer or multi-layer substrate of a material selected from, but not limited to, polyimide, polyethylene terephthalate, polyethylene naphthalate, polycarbonate, polyethersulfone, polyarylate, polysulfone, and cyclic olefin copolymer. For example, the substrate 110 may be a ceramic substrate or a glass substrate.

A pixel driving circuit 20 may be disposed in the display area AA on the substrate 110. The pixel driving circuit 20 may include a plurality of thin film transistors using an amorphous silicon semiconductor, a polycrystalline silicon semiconductor, or an oxide semiconductor.

The pixel driving circuit 20 may include at least one driving thin film transistor, at least one switching thin film transistor, and at least one storage capacitor. When the pixel driving circuit 20 includes the plurality of thin film transistors, it may be formed on the substrate 110 by a thin film transistor (TFT) manufacturing process. In an embodiment, the pixel driving circuit 20 may be a collective term for the plurality of thin film transistors electrically connected to the light-emitting element 10.

The pixel driving circuit 20 may be a driving driver manufactured using a metal-oxide-silicon field effect transistor (MOSFET) manufacturing process on a single crystal semiconductor substrate 110. The driving driver may include the plurality of pixel driving circuits to drive the plurality of sub-pixels. When the pixel driving circuit 20 is implemented as the driving driver, an adhesive layer may be disposed on the substrate 110 and then the driving driver may be mounted on the adhesive layer by a transfer process.

A buffer layer 121 covering the pixel driving circuit 20 may be disposed on the substrate 110. The buffer layer 121 may be made of an organic insulating material, e.g., photosensitive photoacryl or photosensitive polyimide, but is not limited thereto.

The buffer layer 121 may be formed by stacking an inorganic insulating material, e.g., silicon nitride (SiNx) or silicon oxide (SiO₂), in multiple layers, or by stacking an organic insulating material and an inorganic insulating material in multiple layers.

An insulating layer 122 may be disposed on the buffer layer 121. The insulating layer 122 may be made of an organic insulating material, e.g., photosensitive photoacryl or photosensitive polyimide, but is not limited thereto. A connection wire may be disposed on the buffer layer 121. The connection wire may include a plurality of connection wires, such as a first connection wire RT1 and a second connection wire RT2. The connection wires may be connected to the corresponding signal wires TL. The signal wires may include the first signal wire TL1 to the sixth signal wire TL6, but are not limited thereto. The connection wire may include a plurality of wire patterns disposed in different layers with one or more insulating layers interposed therebetween. The wire patterns disposed in different layers may be electrically connected through a contact hole penetrating the insulating layer.

A plurality of bank patterns 130 (also referred to as banks herein) may be disposed on the insulating layer 122. At least one light-emitting element 10 may be disposed above each bank pattern 130. For example, a first light-emitting element 11 may be disposed above a first bank pattern 130a, a second light-emitting element 12 may be disposed above a second bank pattern 130b, and a third light-emitting element 13 may be disposed above a third bank pattern 130c. In some embodiments, a bank 130 includes a plurality of protrusion portions. In some embodiments, the at least one light-emitting element 10 is disposed on one of the plurality of protrusion portions. For example, a first light-emitting element 11 may be disposed on a first protrusion portion of the bank 130, a second light-emitting element 12 may be disposed on a second protrusion portion of the bank 130, and a third light-emitting element 13 may be disposed on a third protrusion portion of the bank 130.

The bank pattern 130 may be made of an organic insulating material, e.g., photosensitive photoacryl or photosensitive polyimide, but is not limited thereto. The bank pattern 130 and/or the protrusion portions of the bank 130 may guide a position to which the light-emitting element 10 is to be attached in the transfer process of the light-emitting element 10. In some embodiments, the bank pattern 130 may be omitted.

A solder pattern 162 may be disposed on the first electrode 161. The solder pattern 162 may be made of indium (In), tin (Sn), gold (Au), or an alloy thereof, but is not limited thereto. The solder pattern 162 may be formed by eutectic bonding of at least two metals selected from indium (In), tin (Sn), or gold (Au).

The plurality of light-emitting elements 10 may be mounted on the solder patterns 162, respectively. One pixel may include three colors of light-emitting elements 10. The first light-emitting element 11 may be a red light-emitting element, the second light-emitting element 12 may be a green light-emitting element, and the third light-emitting element 13 may be a blue light-emitting element. Two light-emitting elements may be mounted in each sub-pixel.

The first optical layer 141 may cover the plurality of light-emitting elements 10 and the plurality of bank patterns 130. Accordingly, the first optical layer 141 may cover between the plurality of light-emitting elements 10 and between the plurality of bank patterns 130. The first optical layer 141 may extend in the first direction X and be disposed separated in the second direction Y to separate the pixels arranged to be spaced apart from each other in the second direction Y. Accordingly, the first optical layer 141 may be separated between the pixel rows. Here, the row may mean the first direction. In addition, a single pixel row composed of the plurality of pixels arranged along the first direction may be referred to as a pixel group. Accordingly, the display panel may include a plurality of pixel groups disposed to be spaced apart from each other in the second direction. For example, since the first optical layer 141 disposed along the first direction is disposed around the pixels and the plurality of first optical layers 141 corresponding to the plurality of pixel groups are disposed to be spaced apart from each other in the second direction, one first optical layer 141 disposed around the pixels forming a single row may be separated from another first optical layer 141 disposed around the pixels forming another row.

The first optical layer 141 may contain an organic insulating material in which fine metal particles such as titanium dioxide particles are dispersed. Light emitted from the plurality of light-emitting elements 10 may be scattered by the fine metal particles dispersed in the first optical layer 141 and emitted to the outside.

The second electrode 170 may be disposed on the plurality of light-emitting elements 10. The second electrode 170 may be connected in common to the plurality of pixels PXL. The second electrode 170 may be a thin electrode through which light is transmitted. The second electrode 170 may be made of a transparent electrode material, e.g., indium tin oxide (ITO), but is not necessarily limited thereto.

In some embodiments, the second electrode 170 is on light-emitting element 10 of each of a plurality of sub-pixels 11, 12, 13. The second electrode 170 may extend in the first direction (the X-axis direction) and may be spaced apart in the second direction (the Y-axis direction). For example, a single second electrode 170 may be formed to extend in the first direction, and a plurality of second electrodes 170 extending in the first direction may be arranged to be spaced apart from each other in the second direction. In this case, the second electrode 170 may be disposed to correspond to each of the pixels that are spaced apart from each other in the second direction.

The second electrode 170 may include a first region 171 disposed on the top surface of the light-emitting element 10 and the top surface of the first optical layer 141, a second region 172 in contact with the contact electrode 163 and electrically connected to the contact electrode 163, and a third region 173 disposed on the side surface of the first optical layer 141 and connecting the first region 171 to the second region 172.

On the plane, each of the plurality of second electrodes 170 may overlap the first optical layer 141, and the third region 173 may cover the outer side surface of the first optical layer 141.

In some embodiments, the display device also includes a second optical layer 142. The first optical layer 141 surrounds the light-emitting element 10 and the second optical layer 142 is disposed on the first optical layer 141. The second optical layer 142 may be an organic insulating material surrounding the periphery of the first optical layer 141. The second optical layer 142 may be disposed on the insulating layer 122 together with the first optical layer 141. The first optical layer 141 and the second optical layer 142 may contain the same material (e.g., siloxane), but first optical layer 141 may include reflective particles while the second optical layer 142 does not contain reflective particles in some embodiments. For example, the first optical layer 141 may be a siloxane containing titanium oxide (TiOₓ), and the second optical layer 142 may be a siloxane not containing titanium oxide (TiOₓ). However, the present disclosure is not necessarily limited thereto, and the first optical layer 141 and the second optical layer 142 may be formed of the same material or different materials.

According to an embodiment, the second region 172 of the second electrode 170 is connected to the contact electrode while being formed flat as a whole, so that excessive stress is not concentrated at the point of connection to the contact electrode 163. Therefore, the generation of cracks in the second electrode 170 may be effectively prevented or at least reduced.

The second optical layer 142 may cover the second region 172 and the third region 173 of the second electrode 170. The top surface of the second optical layer 142 and the top surface of the first region 171 of the second electrode 170 may form the same plane. That is, the first region 171 and the second optical layer 142 may function as a planarization layer.

As a result, since there is no level difference on the surface on which a black matrix 190 is formed, the pattern of the black matrix 190 may be easily formed on the first optical layer 141 and the second optical layer 142. However, the present disclosure is not necessarily limited thereto, and the top surfaces of the second optical layer 142 and the second electrode 170 may have different heights.

In some embodiments, the black matrix 190 covers at least one of the plurality of light-emitting elements 10. In some embodiments, a sub-pixel (e.g., sub-pixel 11, 12, or 13) includes a first light-emitting element (e.g., light-emitting element 11a, 12a, or 13a) and a second light-emitting element (e.g., light-emitting element 11b, 12b, or 13b) emitting a same-colored light. The black matrix 190 covers one of the first light-emitting element or the second light-emitting element and does not cover a remaining one of the first light-emitting element or the second light-emitting element.

The black matrix 190 may be an organic insulating material to which a black pigment is added. The second electrode 170 may be in contact with the contact electrode 163 below the black matrix 190. A transmission hole 191 through which light from the light-emitting element 10 is emitted to the outside may be formed between patterns of the black matrix 190.

The transmission hole 191 may overlap the light-emitting element 10 in the Z-axis direction, and a partial region of the black matrix 190 may overlap the first optical layer 141 in the Z-axis direction. Here, the Z-axis direction may be referred to as the third direction. Accordingly, the black matrix 190 may overcome a problem in which light emitted from the adjacent light-emitting elements 10 is mixed by the first optical layer 141 and then emitted.

A first-second optical layer (not shown) having the same material as the first optical layer 141 may be additionally disposed between the black matrix 190 and the second electrode 170. The first-second optical layer serves to increase the light efficiency emitted to the front surface.

A cover layer 180 may be an organic insulating material that covers the black matrix 190 and the second electrode 170. In FIGS. 2 and 3, the configurations of the black matrix 190 and the cover layer 180 are omitted.

The contact electrode 163 may be electrically connected to the first connection wire RT1 disposed therebelow, and the first connection wire RT1 may be connected to the pixel driving circuit 20. Therefore, a cathode voltage may be applied to the second electrode 170 through the contact electrode 163. The first electrode 161 may be electrically connected to the second connection wire RT2. This will be described later.

Referring to FIG. 5, the contact electrode 163 and the signal wires TL1 to TL6 may be disposed on the same plane. The pixel driving circuit 20 may be disposed below the contact electrode 163 and the signal wires TL1 to TL6. When the pixel driving circuit 20 is a driving driver, a plurality of driving drivers may be disposed in the display panel.

A passivation layer 133 may expose the contact electrode 160 so that the contact electrode 163 and the second electrode 170 are electrically connected to each other. In addition, the passivation layer 133 may insulate the signal wires TL2 to TL5 from the second electrode 170. Here, the passivation layer 133 may be formed of an inorganic material.

Referring to FIG. 6, the extension portion 161a of the first electrode 161 may extend to one side surface 131 of the bank pattern 130 to be electrically connected to the connection wire RT2 disposed on the buffer layer 121.

The first electrode 161, the extension portion 161a, the signal wire TL, and/or the connection wires RT1 and RT2 may include a single-layer or multi-layer metal layer selected from titanium (Ti), molybdenum (Mo), and/or and aluminum (Al).

The first electrode 161 or the signal wire TL may be formed to have a metal stack structure in which a plurality of metal layers are formed using metal materials of different materials, thicknesses, and the like. In this case, the first electrode 161, the extension portion 161a, and the signal wire TL may be simultaneously formed through the same manufacturing process. Here, the thickness may represent a width between one surface and the other surface of the metal layer disposed in the Z-axis direction.

The first electrode 161 may include a first metal layer ML1 disposed below the solder pattern 162, a second metal layer ML2 disposed below the first metal layer ML1, a third metal layer ML3 disposed below the second metal layer ML2, and a fourth metal layer ML4 disposed below the third metal layer ML3. When the first electrode 161 is formed of the first metal layer ML1, the second metal layer ML2, the third metal layer ML3, and the fourth metal layer ML4, the first electrode 161 may be deposited in the order of the fourth metal layer ML4, the third metal layer ML3, the second metal layer ML2, and the first metal layer ML1, and then patterned by performing a photolithography process and an etching process.

The first metal layer ML1 may be disposed to be in contact with the lower portion of the solder pattern 162 and may be electrically connected to the solder pattern 162.

In addition, the first metal layer ML1 may include a transparent conductive oxide layer such as indium tin oxide (ITO) and/or indium zinc oxide (IZO) having good adhesion and corrosion resistance and acid resistance. Here, the first metal layer ML1 may be referred to as an adhesive layer.

The second metal layer ML2 may be formed of a material having a different resistivity value than the first metal layer ML1 and the third metal layer ML3. In this case, the second metal layer ML2 may be formed of a material that has a lower light reflectivity but a higher resistance value than the third metal layer ML3. For example, the second metal layer ML2 may contain titanium (Ti) and/or molybdenum (Mo).

The third metal layer ML3 may be formed of a material having higher light reflectivity than the first metal layer ML1. In this case, the third metal layer ML3 may be formed of a material having higher light reflectivity than the second metal layer ML2. For example, the third metal layer ML3 may contain aluminum (Al) and/or silver (Ag).

That is, the light reflectivity of the third metal layer ML3 may be greater than the light reflectivity of the first metal layer ML1 and the second metal layer ML2.

The fourth metal layer ML4 may be formed of the same material as the second metal layer ML2. For example, the fourth metal layer ML4 may contain titanium (Ti) and/or molybdenum (Mo).

After forming the first metal layer ML1, a reflective opening OP may be formed in the first electrode 161. The reflective opening OP may be a region in which the first metal layer ML1 and the second metal layer ML2 are removed to expose only a portion of the third metal layer ML3. The reflective opening OP may have a shape surrounding the solder pattern 162 on a plane, and may be circular or quadrangular, but is not limited thereto.

Light emitted from the light-emitting element 10 may be reflected from the surface of the third metal layer ML3 exposed by the reflective opening OP, that is the reflective layer 161b, resulting in an increase in the light efficiency of the display device.

In some embodiments, the first electrode 161 includes a reflective layer. In some embodiments, the first electrode 161 includes a reflective metal layer (e.g., the third metal layer ML3) and a non-reflective metal layer (e.g., the first metal layer ML1 and/or the second metal layer ML2) on the reflective metal layer. A part of the reflective metal layer is exposed by an opening (e.g., opening OP) in the non-reflective metal layer to form the reflective layer. In some embodiments, the non-reflective metal layer extends on a top surface of the bank 130, and the part of the reflective metal layer exposed by the opening in the non-reflective metal layer is on the top surface of the bank 130. In some embodiments, the optical layer 141 is between the reflection layer and the light-emitting element 10.

The passivation layer 133 may include an opening hole 133a disposed on the first electrode 161 and the signal wire TL and exposing the solder pattern 162. Here, the opening hole 133a exposing the solder pattern 162 may be referred to as a first opening hole. In this case, the reflective opening OP may be formed to surround the first opening hole.

The light-emitting element 10 may include a first conductivity type semiconductor layer 10-1, an active layer 10-2 disposed on the first conductivity type semiconductor layer 10-1, and a second conductivity type semiconductor layer 10-3 disposed on the active layer 10-2. A first driving electrode 15 may be disposed below the first conductivity type semiconductor layer 10-1 and a second driving electrode 14 may be disposed above the second conductivity type semiconductor layer 10-3.

The light-emitting element 10 may be formed on a silicon wafer by using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering.

The first conductivity type semiconductor layer 10-1 may be implemented with a compound semiconductor such as a group III-V or a group II-VI and may be doped with a first dopant. The first conductivity type semiconductor layer 10-1 may be formed of one or more of a semiconductor material having a composition formula of Alₓ₁In_{y1}Ga_{(1-x1-y1)} N (0≤x1≤1, 0≤y1≤1, 0≤x1+y1≤1), InAlGaN, AlGaAs, GaP, GaAs, GaInP, and AlGaInP, but is not limited thereto. When the first dopant is an n-type dopant such as Si, Ge, Sn, Se, or Te, the first conductivity type semiconductor layer 10-1 may be an n-type nitride semiconductor layer. However, when the first dopant is a p-type dopant, the first conductivity type semiconductor layer 10-1 may be a p-type nitride semiconductor layer.

The active layer 10-2 is a layer in which electrons (or holes) injected through the first conductivity type semiconductor layer 10-1 and holes (or electrons) injected through the second conductivity type semiconductor layer 10-3 meet. The active layer 10-2 transitions to a low energy level as the electrons and the holes recombine, and may generate light having a wavelength corresponding thereto.

The active layer 10-2 may have any one structure selected from a single well structure, a multi-well structure, a single quantum well structure, a multi-quantum well (MQW) structure, a quantum dot structure, or a quantum wire structure, but the structure of the active layer 10-2 is not limited thereto. The active layer 10-2 may generate light in a visible wavelength band. For example, the active layer 10-2 may output light in any one of blue, green, and red wavelength bands.

The second conductivity type semiconductor layer 10-3 may be disposed on the active layer 10-2. The second conductivity type semiconductor layer 10-3 may be implemented with a compound semiconductor such as a group III-V or a group II-VI, and may be doped with a second dopant. The second conductivity type semiconductor layer 10-3 may be formed of a semiconductor material having a composition formula of Inₓ₂Al_{y2}Ga_{1-x2-y2}N (0≤x2≤1, 0≤y2≤1, 0≤x2+y2≤1), or a material selected from AlInN, AlGaAs, GaP, GaAs, GaAsP, AlGaInP, and AlGaInP. When the second dopant is a p-type dopant such as Mg, Zn, Ca, Sr, or Ba, the second conductivity type semiconductor layer 10-3 doped with the second dopant may be a p-type nitride semiconductor layer. When the second dopant is an n-type dopant, the second conductivity type semiconductor layer 10-3 may be an n-type nitride semiconductor layer.

In an embodiment, although a vertical structure has been described in which the driving electrodes 14 and 15 are disposed above and below the light-emitting structure, the light-emitting element may have a lateral structure or a flip chip structure other than the vertical structure.

Referring to FIG. 7, the main light-emitting element 12a and the sub-light-emitting element 12b of the sub-pixel may be disposed on the bank pattern 130. The second light-emitting element 12 is exemplarily described. A first-first electrode 161-1 connected to the main light-emitting element 12a may extend to one side surface of the bank pattern 130 to be electrically connected to a second-first connection wire RT21 disposed therebelow. A first-second electrode 161-2 connected to the sub-light-emitting element 12b may extend to the other side surface of the bank pattern 130 to be electrically connected to a second-second connection wire RT22 disposed therebelow.

The pixel driving circuit 20 may apply an anode voltage to the main light-emitting element 12a through the second-first connection wire RT21, and may apply an anode voltage to the sub-light-emitting element 12b through the second-second connection wire RT22. The pixel driving circuit 20 may apply a cathode voltage to the main light-emitting element 12a and the sub-light-emitting element 12b through the first connection wire RT1 and the second electrode 170.

The pixel driving circuit 20 may adjust the luminance by driving only the main light-emitting element 12a, or may adjust the luminance by simultaneously driving the main light-emitting element 12a and the sub-light-emitting element 12b. When the main light-emitting element 12a is turned into a dark point, the luminance may be adjusted by driving only the sub-light-emitting element 12b.

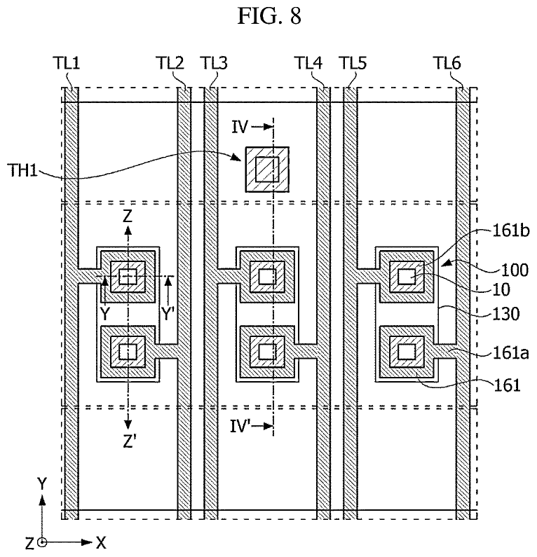

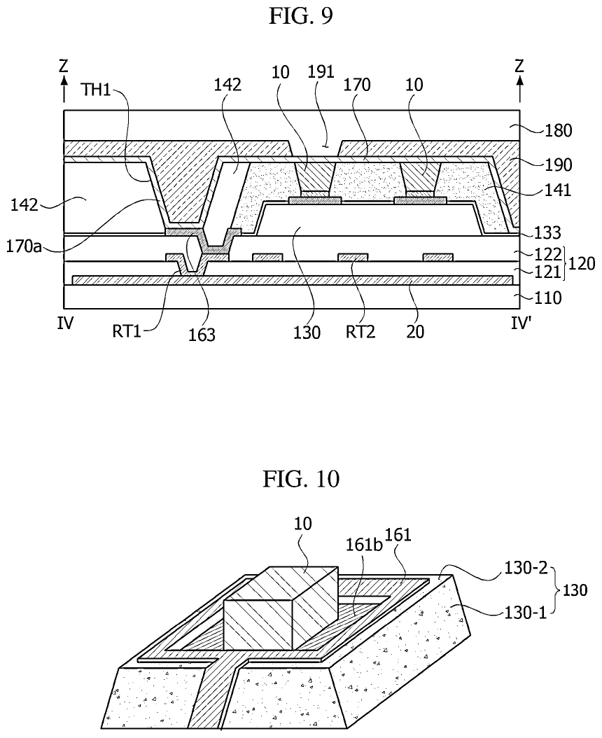

FIG. 8 is a diagram illustrating a display device according to one embodiment of the present specification. FIG. 9 is a cross-sectional view taken along line IV-IV′ in FIG. 8 according to one embodiment of the present specification.

Referring to FIGS. 8 and 9, the second electrode 170 may be electrically connected to the contact electrode 163 through a contact hole TH1 formed in the second optical layer 142. The second optical layer 142 may include the contact hole TH1 exposing the contact electrode 163. The second electrode 170 inserted into the contact hole TH1 of the second optical layer 142 may be in contact with the top surface of the contact electrode 163. The contact hole TH1 may be formed in an outer region of the pixel. In some embodiments, the contact electrode 163 is on one of the one or more insulating layers 122. The contact hole TH1 penetrates the first optical layer 141 and/or the second optical layer 142. The second electrode 170 is in contact with the contact electrode 163 through the contact hole TH1.

FIG. 10 is a diagram illustrating a partial area of a pixel according to another embodiment of the present disclosure. Hereinafter, the description will be given focusing on a portion different from those of FIGS. 2 and 3.

The plurality of first electrodes 161 may each be disposed under the light-emitting element 10, and may be selectively connected to the plurality of signal wires TL1 to TL6 by the extension portion 161a. The extension portion 161a may be less than or equal to the length of one surface of the first electrode 161. The high potential voltage may be applied to the pixel driving circuit through the signal wires TL to TL6. The signal wires TL to TL6 and the first electrode 161 may be formed as an integrated electrode pattern during the electrode patterning process.

For example, the first signal wire TL1 may be connected to the anode electrode of the first red sub-pixel, and the second signal wire TL2 may be connected to the anode electrode of the second red sub-pixel. The third signal wire TL3 may be connected to the anode electrode of the first green sub-pixel, and the fourth signal wire TL4 may be connected to the anode electrode of the second green sub-pixel. The fifth signal wire TL5 may be connected to the anode electrode of the first blue sub-pixel, and the sixth signal wire TL6 may be connected to the anode electrode of the second blue sub-pixel. When one sub-pixel includes only one light-emitting element, the number of the signal wires TL may be reduced by half.

The second electrode 170 may be a cathode electrode that is disposed in each row and applies a cathode voltage to the light-emitting elements 10 arranged successively in the first direction (the X-axis direction). The plurality of second electrodes 170 may be spaced apart from each other in the second direction (the Y-axis direction). The plurality of second electrodes 170 may be connected to the cathode voltage through the contact electrode 163. Each of the plurality of second electrodes 170 may be electrically connected to the contact electrode 163. However, the present disclosure is not necessarily limited thereto, and the second electrode 170 may be configured as one electrode layer without being divided into a plurality of electrodes and may function as a common electrode.

A reflection layer 161b is disposed on the first electrode 161. The reflection layer 161b may have a shape surrounding a region in which the first electrode 161 and the solder pattern 162 are in contact with each other. The reflection layer 161b may be formed by depositing a reflective material on the first electrode 161. When the first electrode 161 is composed of a plurality of metal layers, including a reflective metal layer positioned below and a non-reflective metal layer positioned thereon, the reflection layer 161b may be formed by removing the non-reflective metal layer to expose the reflective metal layer. In particular, among the first electrodes 161, the exposed surface of the reflective metal layer ML3 may be used as the reflective layer 161b. In this case, the reflection layer 161b may be formed in the same manner as the reflective opening OP shown in one embodiment of FIG. 6. But, it is not limited to this.

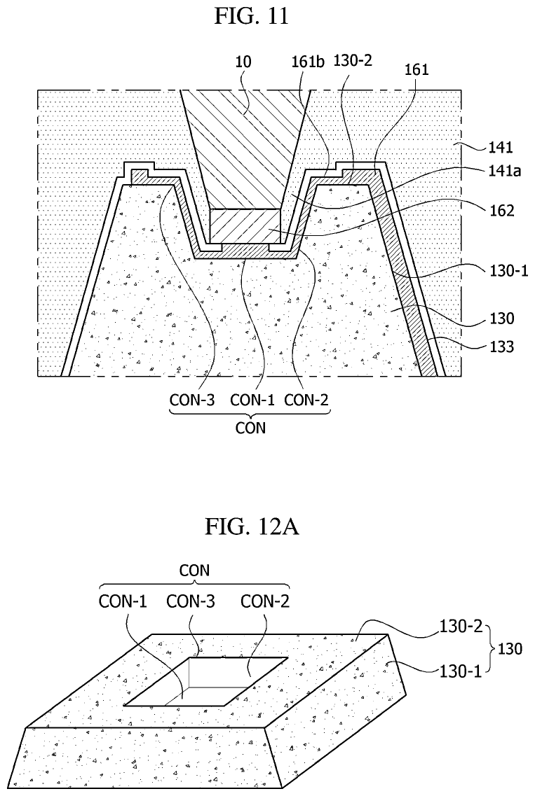

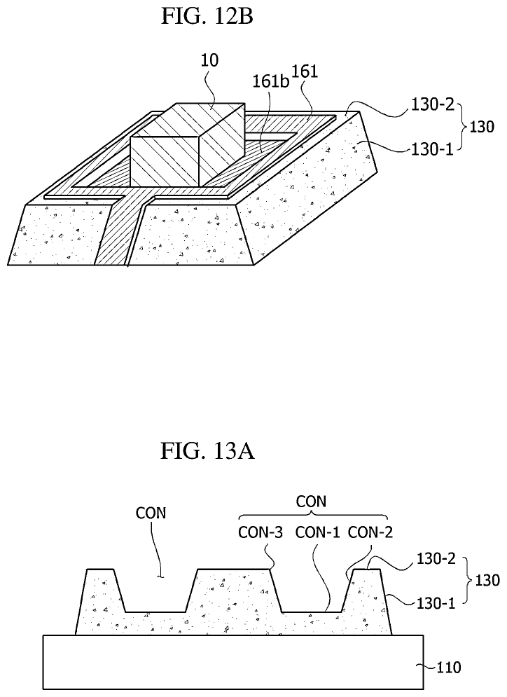

FIG. 11 is a cross-sectional view taken along line Y-Y′ in FIG. 8. FIGS. 12A and 12B are perspective views of the fabricating process of a display device according to one embodiment of the present disclosure.

FIGS. 11, 12A, and 12B show only the components corresponding to the bank pattern 130, the first electrode 161, the light-emitting element 10, the reflection layer 161b, a first optical layer 141, the solder pattern 162, and a concave portion CON, and other components are the same as those in the configuration of FIG. 6. In some embodiments, the bank 130 includes a plurality of protrusion portions. At least one of the plurality of protrusion portions includes a concave portion CON. The first electrode 161 is disposed in the concave portion CON, the light-emitting element is disposed on the first electrode 161 at least in part in the concave portion, and a second electrode 170 is disposed on the light-emitting element 10.

Referring to FIGS. 11, 12A, and 12B, the concave portion CON is formed in the bank pattern 130. The center of the concave portion CON may coincide with the center of the bank pattern 130, but the present disclosure is not limited thereto. The top CON-3 and bottom surfaces CON-1 of the concave portion CON may have a circular shape, a quadrilateral shape, or a shape in which only the corners of the edge are rounded, but are not limited thereto. The depth of the concave portion CON may be defined as a vertical distance between the top CON-3 and bottom surface CON-1 of the concave portion CON. That is, the depth of the concave portion CON may be defined as a distance between the upper and the upper surface of the side surface CON-2 of the concave portion CON and the bottom surface CON-1 of the concave portion below the side surface.

The depth of the concave portion CON may be smaller than the height of the light-emitting element 10, such that the light-emitting element 10 is disposed in part in the concave portion CON. The top surface of the light-emitting element 10 is farther from the substrate 110 than the bottom surface of the light-emitting element 10. In some embodiments, an area of a bottom surface CON-1 of the concave portion CON is greater than an area of a bottom surface of the light-emitting element 10. The area of the bottom surface CON-1 and the open area of the top CON-3 of the concave portion CON are larger than the area of the lower surface of the light-emitting element 10. In some embodiments, the area of the bottom surface CON-1 of the concave portion CON is 1.2 to 1.5 times the area of the lower surface of the light-emitting element 10.

This is to prevent or at least reduce incorrect transfer or misplacement of the light-emitting element 10 to the inner side surface CON-2 of the concave portion CON or the top surface 130-2 of the bank pattern 130 due to a transfer tolerance when transferring the light-emitting element 10 to the bottom surface CON-1 of the concave portion CON. In addition, as will be described later, this is to prevent or at least reduce the problem of the light-emitting element 10 being removed together with the first-first optical layer during the process of removing and reapplying the first-first optical layer due to defects found therein after the first-first optical layer is initially applied.

Since the active layer 10-2 of the light-emitting element 10 has a different light efficiency for each color, the size of the light-emitting element 10 may be different for each color. Accordingly, the areas of the top and bottom surfaces of the concave portion CON may also be different depending on the color of light emitted by the light-emitting element 10. The area of the top surface of the light-emitting element 10 may be larger than the area of the bottom surface thereof. For example, when the light emitting element 10 has a rectangular shape, that is the length of each side of the upper surface of the light-emitting element 10 may be longer than the length of each side of the bottom surface facing each side.

In some embodiments, the light-emitting element is a micro LED, and a size of a light-emitting element emitting a first colored light is different from a size of a light emitting element emitting a second colored light. In some embodiments, a size of a first concave portion of a bank pattern in which the light-emitting element emitting the first colored light is disposed is different from a size of a second concave portion of the bank pattern in which the light-emitting element emitting the second colored light is disposed.

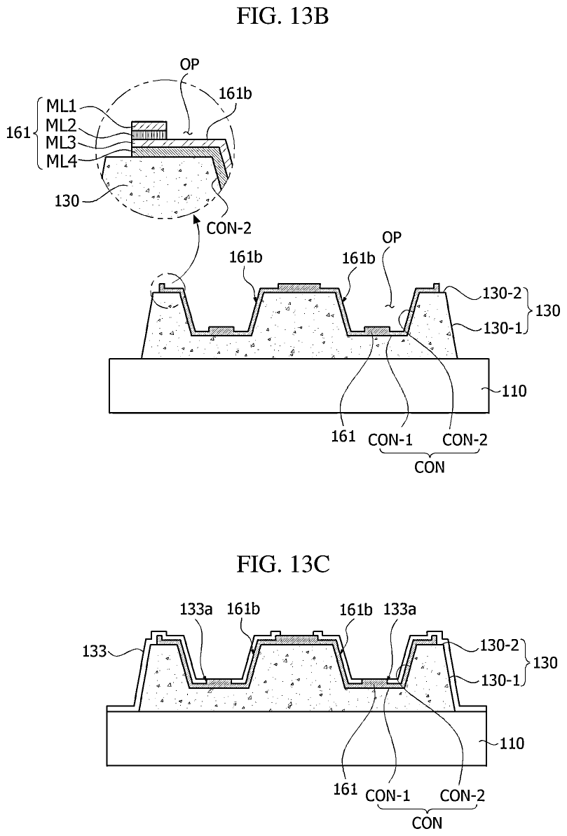

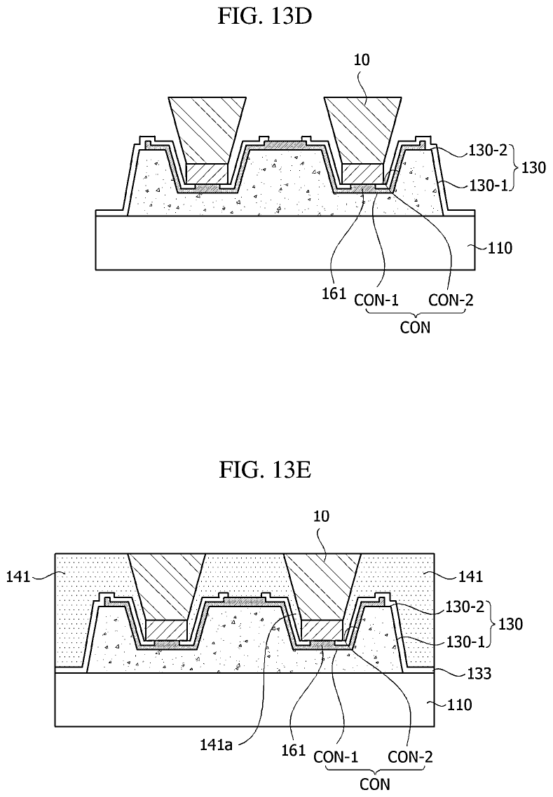

FIGS. 13A to 13E are cross-sectional views of the fabricating process of a display device in a direction Z-Z′ of FIG. 8 according to one embodiment of the present disclosure.

Referring to FIGS. 13A to 13E, the fabricating process of a display device according to one embodiment of the present disclosure is as follows.

Referring to FIG. 13A, the bank pattern 130 is formed on the substrate 110. When forming the bank pattern 130, a halftone mask is used in a photolithography process. The concave portion CON may be formed in the upper surface 130-2 of the bank pattern 130 using the halftone mask. The central portion of the concave portion CON may coincide with the central portion of the bank pattern 130, but is not limited thereto. The top CON-3 and bottom surface CON-1 of the concave portion CON may have a circular shape, a rectangular shape, and a rounded edge, but are not limited thereto. The depth of the concave portion CON may be defined as a vertical distance from the top end of the side surface CON-2 of the concave portion CON to the bottom surface CON-1 of the concave portion below the side surface CON-2.

The depth of the concave portion CON may be less than the height of the light emitting element 10, such that the light-emitting element is partially disposed in the concave portion CON. In some embodiments, an area of the bottom surface CON-1 of the concave portion CON is greater than an area of a bottom surface of the light-emitting element. The bottom surface CON-1 and the top CON-3 of the concave portion CON are wider than the area of the bottom surface of the light emitting element 10, for example, the area of the bottom surface CON-1 may be 1.2 to 1.5 times the area of the bottom surface of the light emitting element 10. Referring to FIG. 13B, the first electrode 161 is formed to cover the inner surface of the concave portion CON, that is the bottom surface CON-1 and the side surface CON-2 and at least a portion of the top surface 130-2 of the bank pattern 130. Thereafter, a reflective metal such as aluminum is deposited in the reflection layer 161b. In addition, the first electrode 161 may be formed to extend over the upper surface 130-2 and the side surface 130-1 of the bank pattern 103. In this case, the first electrode 161 may be formed by sequentially depositing a plurality of metal layers, for example, a fourth metal layer ML4, a third metal layer ML3, a second metal layer ML2, and a first metal layer ML1. In this case, the third metal layer ML3 may be deposited with a reflective metal such as aluminum. However, the present disclosure is not limited thereto.

In some embodiments, the reflection layer 161b is on the bottom surface CON-1 and a side surface CON-2 of the concave portion CON. In some embodiments, the reflection layer 161b surrounds where the first electrode 161 and the light-emitting element 10 are in contact with each other.

Subsequently, referring to FIG. 13B, among a plurality of metal layers constituting the first electrode 161, for example, the first and second metal layers ML1 and ML2, which are non-reflective metal layers, are removed to expose the surface of the third metal layer ML3, which is a reflective metal layer, on the upper surface of the first electrode 161 to form a reflective layer 161b. In some embodiments, the reflection layer 161b is a part of the first electrode 161. In some embodiments, the first electrode 161 includes a reflective metal layer ML3 and a non-reflective metal layer ML1 and/or ML2. A part of the reflective metal layer ML3 layer is exposed by an opening in the non-reflective metal layer ML1 and/or ML2 to form the reflection layer 161b. In some embodiments, the non-reflective metal layer ML1 and/or ML2 extends on a top surface of the bank 130, and the part of the reflective metal layer ML3 exposed by the opening in the non-reflective metal layer is on the top surface 130-2 of the bank 130.

In some embodiments, the reflective layer 161b may include the entire surface of the third metal layer ML3 of the first electrode 161 that is exposed. In some embodiments, the reflective layer 161b may include an inner surface of the concave portion CON. The inner surface may include the entire side surface CON-2 and a portion of the bottom surface CON-1, where an exposed surface area of the third metal layer ML3 constituting the first electrode 161 positioned on a portion of the upper surface 130-2 of the bank pattern 130. However, the reflective layer 161b may not include a portion of the bottom surface CON-1 of the concave portion CON, where the first metal layer ML1 of the first electrode 161 is in contact with the bottom surface of the light emitting device 10 when the light emitting device 10 is transferred into the concave portion CON. In some embodiments, a solder pattern 162 may be formed between the light emitting device 10 and the first electrode 161.

As another configuration, a reflective metal layer may be deposited on the first electrode 161 to form a reflective layer.

Thereafter, referring to FIG. 13C, the passivation layer 133 may be formed on the entire surface of the bank pattern 130 including the first electrode 161 and the reflective layer 161b. Thereafter, the passivation layer 133 may be selectively patterned to form an opening hole 133a exposing a portion of the first electrode 161 in contact with the light emitting device 10. In this case, a portion of the upper surface of the first electrode 161 positioned at the center of the bottom surface CON-1 of the concave portion CON may be exposed by the opening hole 133a.

Subsequently, referring to FIG. 13D, the light emitting device 10 may be transferred on the exposed portion of the first electrode 161 on the inner bottom surface CON-1 of the concave portion CON to be electrically connected to the first electrode 161.

Referring to FIG. 13E, the first optical layer 141 is applied to surround the entire light-emitting element 10. In this case, the first optical layer 141 may be disposed on the bank pattern 130 and the side surface of the light emitting element 10. In some embodiments, the optical layer 141 is between the reflection layer 161b and the light-emitting element 10 within the concave portion CON. In addition, a portion 141a of the first optical layer 141 may also be filled in a space between the side surface of the light emitting element 10 and the reflection layer 161b in the concave portion CON. In this case, a portion 141a of the first optical layer 141 may serve not only to support the light emitting element 10 not to be separated from the concave portion CON, but also to improve light reflection efficiency. In this case, due to a process problem, there may be a case where the optical layer does not cover the light-emitting element 10 and the surface of the light-emitting element 10 is exposed. Accordingly, there may be a problem that the exposed light-emitting element 10 is lost during the process of removing the optical layer with a chemical solution and removing the remaining chemical solution or foreign matter using a DI water and air knife. For this reason, when a defect occurs in the optical layer, repair is impossible, and the display panel itself needs to be discarded, resulting in an increase in the cost of product production.

According to one embodiment of the present disclosure, the light-emitting element 10 may be transferred to the bottom surface of the concave portion CON in the bank pattern 130, so that the concave portion 10 may act as a breakwater or a dam to prevent or at least reduce the loss of the light-emitting element 10 caused by water pressure or wind pressure during the process of removing the remaining chemical solution or foreign matter described above. As a result, even if a defect occurs in the optical layer, the optical layer may be removed and reapplied to continue product production, thereby reducing costs.

In an embodiment, a vertical structure has been described in which the driving electrodes 14 and 15 are disposed on the top and bottom of the light-emitting structure, but the light-emitting element may have a lateral structure or a flip chip structure other than the vertical structure.

The display device according to embodiments of the present disclosure may be applied to mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic books, portable multimedia players (PMPs), personal digital assistants (PDAs), MP3 players, mobile medical apparatuses, desktop personal computers (PCs), laptop PCs, netbook computers, workstations, navigation apparatuses, automotive display apparatuses, theater displays, televisions (TVs), wallpaper apparatuses, signage apparatuses, notebook computers, monitors, cameras, camcorders, home appliances, and the like. In addition, a display device manufactured through a light-emitting element transfer stamp and a light-emitting element transfer method using a transfer stamp according to one or more embodiments of the present disclosure may be applied to an organic light-emitting lighting device or an inorganic light-emitting lighting device.

A display device according to one or more embodiments of the present disclosure may be described as follows.

A display device according to one or more embodiments of the present disclosure may comprise a substrate, a plurality of bank patterns disposed on the substrate, a plurality of concave portions formed in each of the plurality of bank patterns, a first electrode disposed in the concave portions, a reflection layer disposed on the first electrode, a light-emitting element disposed on the first electrode in the concave portion, and a first optical layer disposed to surround the side surface of the light-emitting element.

The display device may further include a second optical layer disposed on the light-emitting element, and a second electrode disposed between the first optical layer and the second optical layer.

The bottom surface of the concave portion may have a shape of one of a quadrilateral, a circle, or a quadrilateral with four rounded corners on a plane.

A plurality of the light-emitting elements may be disposed in the concave portions formed in the plurality of bank patterns adjacent to each other are arranged such that in a first direction, light-emitting elements that emit light of different colors may be arranged in the order of red, green, and blue, and in a second direction perpendicular to the first direction, light-emitting elements that emit light of the same color may be arranged, and wherein the light-emitting elements that emit light of different colors may have different sizes.

The reflection layer may be disposed to surround a contact portion of the light-emitting element and the first electrode.

The first electrode may be formed by sequentially stacking a reflective metal and a non-reflective metal, and the reflection layer may be formed by removing the non-reflective metal of the first electrode.

A depth of the concave portion may be smaller than a height of the light-emitting element.

The display device may further comprise a solder pattern disposed between the light-emitting element and the first electrode, wherein the solder pattern is formed by eutectic bonding of at least two of indium, tin, or gold.

The display device may further comprise an insulating layer disposed on the substrate, an adhesive layer disposed on the insulating layer, a pixel driving circuit disposed on the adhesive layer, a buffer layer disposed on the pixel driving circuit, and a plurality of connection wires disposed between the pixel driving circuit and the insulating layer, wherein the pixel driving circuit is connected to the plurality of connection wires, and the plurality of connection wires are electrically connected to the first electrode.

A method for fabricating a display device according to one or more embodiments of the present disclosure may comprise preparing a substrate, arranging a plurality of bank patterns on the substrate, forming at least one concave portion in each of the plurality of bank patterns, disposing a first electrode on the concave portion, forming a reflection layer on the first electrode, forming a light-emitting element on the first electrode in the concave portion, and disposing a first optical layer to surround the side surface of the light-emitting element.

The method may further include disposing a second optical layer on the light-emitting element, and disposing a second electrode on the first optical layer.

The bottom surface of the concave portion may have a shape of one of a quadrilateral, a circle, or a quadrilateral with four rounded corners in plan view.

The plurality of the light-emitting elements may be disposed in the concave portions formed in the plurality of bank patterns adjacent to each other are arranged such that in a first direction, light-emitting elements that emit light of different colors may be arranged in the order of red, green, and blue, and in a second direction perpendicular to the first direction, light-emitting elements that emit light of the same color may be arranged, wherein the light-emitting elements that emit light of different colors may have different sizes.

The reflection layer may be disposed to surround a contact portion of the light-emitting element and the first electrode.

The first electrode may be formed by sequentially stacking a reflective metal and a non-reflective metal, and the reflection layer may be formed by removing the non-reflective metal of the first electrode.

A depth of the concave portion may be smaller than a height of the light-emitting element.

The method may further include disposing a solder pattern between the light-emitting element and the first electrode, wherein the solder pattern is formed by eutectic bonding of at least two of indium, tin, or gold.

The method may further include disposing an insulating layer on the substrate, disposing an adhesive layer on the insulating layer, disposing a pixel driving circuit on the adhesive layer, disposing a buffer layer on the pixel driving circuit, and disposing a plurality of connection wires between the pixel driving circuit and the insulating layer, wherein the pixel driving circuit is connected to the plurality of connection wires, and the plurality of connection wires are electrically connected to the first electrode.

A display device includes a substrate, a pixel driving circuit on the substrate, one or more insulating layers on the pixel driving circuit, and a bank including a plurality of protrusion portions on the one or more insulating layers. At least one of the plurality of protrusion portions includes a concave portion. The display device further includes a pixel. The pixel includes a plurality of sub-pixels. At least one of the plurality of sub-pixels includes a first electrode in the concave portion, a light-emitting element disposed on the first electrode at least in part in the concave portion, and a second electrode on the light-emitting element. An area of a bottom surface of the concave portion is greater than an area of a bottom surface of the light-emitting element.

In some embodiments, at least one of the plurality of sub-pixels further includes a reflection layer surrounding where the first electrode and the light-emitting element are in contact with each other. In some embodiments, the reflection layer is on the bottom surface and a side surface of the concave portion. In some embodiments, the reflection layer is a part of the first electrode. In some embodiments, the first electrode includes a reflective metal layer and a non-reflective metal layer on the reflective metal layer. A part of the reflective metal layer is exposed by an opening in the non-reflective metal layer to form the reflection layer. In some embodiments, the non-reflective metal layer extends on a top surface of the bank, and the part of the reflective metal layer exposed by the opening in the non-reflective metal layer is on the top surface of the bank.

In some embodiments, the display device further includes an optical layer. The optical layer is between the reflection layer and the light-emitting element within the concave portion. In some embodiments, the optical layer includes a first optical layer surrounding the light-emitting element of the at least one of the plurality of sub-pixels, and a second optical layer on the first optical layer. In some embodiments, the first optical layer includes an organic material dispersed with reflective particles. In some embodiments, the first optical layer and the second optical layer include a same organic material. In some embodiments, the first optical layer includes an organic material disposed with reflective particles, and the second optical layer includes the organic material without reflective particles.

In some embodiments, the display device further includes a black matrix covering the light-emitting element of the at least one of the plurality of sub-pixels. In some embodiments, the at least one of the plurality of sub-pixels includes a first light-emitting element and a second light-emitting element emitting a same-colored light. In some embodiments, the black matrix covers one of the first light-emitting element or the second light emitting element and does not cover a remaining one of the first light-emitting element or the second light-emitting element.

In some embodiments, the light-emitting element is a micro light-emitting diode (LED), and a size of a light-emitting element emitting a first color is different from a size of a light-emitting element emitting a second color. In some embodiments, a size of a first concave portion in which the light-emitting element emitting the first color is disposed is different from a size of a second concave portion in which the light-emitting element emitting the second color is disposed.

In some embodiments, the first electrode is on a top surface and a side surface of the at least one of the plurality of protrusion portions of the bank. In some embodiments, the second electrode is on the light-emitting element of the at least one of the plurality of sub-pixels. In some embodiments, at least one of the plurality of sub-pixels includes a first light-emitting element and a second light-emitting element emitting a same colored light.

The effects of the present disclosure are not limited to the effects mentioned above, and other effects not mentioned may be clearly understood by those skilled in the art from the description of the claims.

While the embodiments have been described in detail above with reference to the accompanying drawings, the present disclosure is not necessarily limited to these embodiments, and various changes and modifications may be made without departing from the technical spirit of the present disclosure. Accordingly, the embodiments disclosed herein are to be considered descriptive and not restrictive of the technical spirit of the present disclosure, and the scope of the technical spirit of the present disclosure is not limited by these embodiments. Therefore, the above-described embodiments should be understood to be exemplary and not limiting in any aspect.

What is claimed is:

1. A display device comprising:
a substrate;
a pixel driving circuit on the substrate;
one or more insulating layers on the pixel driving circuit;
a bank including a plurality of protrusion portions on the one or more insulating layers, at least one of the plurality of protrusion portions including a concave portion;
a pixel including a plurality of sub-pixels, at least one of the plurality of sub-pixels including:
a first electrode in the concave portion;
a light-emitting element disposed on the first electrode at least in part in the concave portion; and
a second electrode on the light-emitting element,
wherein an area of a bottom surface of the concave portion is greater than an area of a bottom surface of the light-emitting element.

2. The display device of claim 1, wherein the at least one of the plurality of sub-pixels further includes a reflection layer on the bottom surface and a side surface of the concave portion.

3. The display device of claim 1, wherein the at least one of the plurality of sub-pixels further includes a reflection layer surrounding where the first electrode and the light-emitting element are in contact with each other.

4. The display device of claim 3, wherein the reflection layer is a part of the first electrode.

5. The display device of claim 4, wherein the first electrode includes a reflective metal layer and a non-reflective metal layer on the reflective metal layer, a part of the reflective metal layer being exposed by an opening in the non-reflective metal layer to form the reflection layer.

6. The display device of claim 5, wherein the non-reflective metal layer extends on a top surface of the bank, and the part of the reflective metal layer exposed by the opening in the non-reflective metal layer is on the top surface of the bank.

7. The display device of claim 3, further comprising an optical layer, wherein the optical layer is between the reflection layer and the light-emitting element within the concave portion.

8. The display device of claim 7, further comprising:
a contact electrode on one of the one or more insulating layers; and
a contact hole through the optical layer, the second electrode being in contact with the contact electrode through the contact hole.

9. The display device of claim 8, wherein the optical layer includes a first optical layer surrounding the light-emitting element of the at least one of the plurality of sub-pixels, and a second optical layer on the first optical layer.

10. The display device of claim 9, wherein the first optical layer includes an organic material dispersed with reflective particles.

11. The display device of claim 10, wherein the first optical layer and the second optical layer include a same organic material.

12. The display device of claim 10, wherein the first optical layer includes an organic material dispersed with reflective particles, and the second optical layer includes the organic material without reflective particles.

13. The display device of claim 1, further comprising:
a black matrix covering the light-emitting element of the at least one of the plurality of sub-pixels.

14. The display device of claim 1, the display device further comprising a black matrix,
wherein the at least one of the plurality of sub-pixels includes a first light-emitting element and a second light-emitting element emitting a same-colored light, and
wherein the black matrix covers one of the first light-emitting element or the second light-emitting element and does not cover a remaining one of the first light-emitting element or the second light-emitting element.

15. The display device of claim 1, wherein the light-emitting element is a micro light-emitting diode (LED), and a size of a light-emitting element emitting a first colored light is different from a size of a light-emitting element emitting a second colored light.

16. The display device of claim 15, wherein a size of a first concave portion in which the light-emitting element emitting the first colored light is disposed is different from a size of a second concave portion in which the light-emitting element emitting the second colored light is disposed.

17. The display device of claim 1, wherein the first electrode is on a top surface and a side surface of the at least one of the plurality of protrusion portions of the bank.

18. The display device of claim 1, wherein the second electrode is on the light-emitting element of each of the plurality of sub-pixels.

19. The display device of claim 1, wherein the at least one of the plurality of sub-pixels includes a first light-emitting element and a second light-emitting element emitting a same-colored light.
